(19) United States
(12) Patent Application Publication
(10) Pub. No.: US 2014/0301053 A1
(43) Pub. Date: Oct. 9, 2014

(54) MULTILAYER CERAMIC SUBSTRATE AND ELECTRONIC COMPONENT USING SAME

(71) Applicant: MURATA MANUFACTURING CO., LTD., Nagaokakyo-shi (JP)

(72) Inventors: Yuichi Iida, Nagaokakyo-shi (JP); Satoru Adachi, Nagaokakyo-shi (JP); Kazuo Kishida, Nagaokakyo-shi (JP)

(21) Appl. No.: 14/311,766

(22) Filed: Jun. 23, 2014

Related U.S. Application Data
(63) Continuation of application No. PCT/JP2012/083651, filed on Dec. 26, 2012.

(30) Foreign Application Priority Data
Dec. 27, 2011 (JP) 2011-285294

(51) Int. Cl. H05K 1/03; H05K 1/02

(52) U.S. Cl. CPC H05K 1/0306; H05K 1/0298
USPC 361/760; 428/212

(57) ABSTRACT

A multilayer ceramic substrate including an inner-layer section, surface-layer sections stacked on opposed principal surfaces of the inner-layer section, and surface electrodes provided on at least one surface of the surface-layer sections. The surface-layer sections contain SiO₂-MO—B₂O₃—Al₂O₃ based glass and an Al₂O₃ filler, wherein MO is at least one selected from the group consisting of CaO, MgO, SrO, and BaO. The coefficient of thermal expansion in the surface-layer sections is lower than the coefficient of thermal expansion in the inner-layer section, and the peak intensity ratio through an XRD analysis between MAl₂Si₂O₈ and Al₂O₃ in the surface-layer sections falls within the range of 0.05≦(MAl₂Si₂O₈/Al₂O₃)≦5, wherein M is at least one selected from the group consisting of Ca, Mg, Sr, and Ba.

### CROSS REFERENCE TO RELATED APPLICATIONS

The present application is a continuation of International application No. PCT/JP2012/083651, filed Dec. 26, 2012, which claims priority to Japanese Patent Application No. 2011-285294, filed Dec. 27, 2011, the entire contents of each of which are incorporated herein by reference.

### FIELD OF THE INVENTION

The present invention relates to a multilayer ceramic substrate and an electronic component using the substrate, and more particularly, relates to a technique for improving the mechanical strength of the multilayer ceramic substrate, the insulation resistance of a surface-layer section thereof, the bonding strength of a surface electrode to the surface-layer section of the multilayer ceramic substrate, etc.

### BACKGROUND OF THE INVENTION

In recent years, multilayer ceramic substrates with three-dimensionally arranged wiring conductors have been widely used for applications, e.g., modules provided with multiple electronic components such as semiconductor devices.

As such a multilayer ceramic substrate, a low-temperature fired multilayer ceramic substrate composed of glass and the remaining crystalline substance in order to improve the transverse strength has been proposed sphere the coefficient of thermal expansion in the outermost layer is lower than the coefficient of thermal expansion in inner-layers (see Patent Document 1).

Further, this multilayer ceramic substrate is considered to experience significant improvement in transverse strength with compressive stress generated in the outermost layer by post-firing cooling, due to the difference in coefficient of thermal expansion.

In addition, a multilayer ceramic substrate including a stacked structure composed of an inner-layer section and surface-layer sections located on both principal surfaces of the inner-layer section, where each of the inner-layer section and surface-layer sections is composed of at least one ceramic layer, has been proposed, which is characterized in that the relationship of 0.3≦α2−α1≦1.5 is met when the coefficient of thermal expansion in the surface-layer sections is referred to as α1 [ppmK⁻¹], whereas the coefficient of thermal expansion in the inner-layer section is referred to as α2 [ppmK⁻¹], and a needle crystal is deposited in the inner-layer section (Patent Document 2).

Further, Patent Document 2 mentions that the inner-layer section preferably contains, for example, borosilicate glass. In addition, at least one of wollastonite, sillimanite, rutile, and mullite, for example, is cited as the needle crystal deposited in the inner-layer section.

In addition, as yet another multilayer ceramic substrate, a multilayer ceramic structure including a stacked structure composed of a surface-layer section and an inner-layer section has been proposed where the relationship between the coefficient of thermal expansion α1 in the surface-layer section and the coefficient of thermal expansion α2 in the inner-layer section meets the relationship of 1.0≦α2−α1≦4.3, and the ratio by weight of a common constituent is 75 weight % or more between the material constituting the surface-layer section and the material constituting the inner-layer section (Patent Document 3).

This multilayer ceramic substrate in Patent Document 3 is supposed to make it possible to improve the transverse strength, and be capable of preventing interlayer peeling (delamination).
Patent Document 1: Japanese Patent Application Laid-Open No. 6-29664
Patent Document 2: Japanese Patent Application Laid-Open No. 2007-73728
Patent Document 3: International publication WO 2007/142112

### SUMMARY OF THE INVENTION

Now, in regard to multilayer ceramic substrates, while it is also important to improve the transverse strength and suppress the interlayer peeling as described above, it is also critically important to increase the strength of bonding between surface electrodes (e.g. electrodes and surface wiring conductors for external conduction) formed on the surfaces of the multilayer ceramic substrates and the surface-layer sections of the multilayer ceramic substrates, and ensure insulation between the surface electrodes and internal electrodes opposed to the surface electrodes with the surface-layer sections interposed therebetween by keeping high insulation properties of the surface-layer sections (ceramic layers) of the multilayer ceramic substrates with the surface electrodes formed thereon.

However, in material systems which utilize glass crystallization as described above in Patent Documents 1 to 3, it is not easy to simultaneously improve the three types of properties: the mechanical strength of the substrate, such as the transverse strength; the strength of bonding between surface electrodes and the surface-layer sections (ceramic layers); and the insulation properties of the surface-layer sections (ceramic layers). More specifically, while there is a need to increase the amount of residual glass by suppressing glass crystallization in the surface-layer sections in order to improve the adhesion between the surface electrodes and the surface-layer sections (ceramic layers) of the multilayer ceramic substrates, the increased amount of residual glass will increase the amount of diffusion of the electrode materials constituting the surface electrodes to the surface-layer sections (ceramic layers) of the multilayer ceramic substrates to decrease the insulation properties of the surface-layer sections (ceramic layers) of the multilayer ceramic substrates.

In addition, depending on the crystallinity of the glass in the surface-layer sections (ceramic layers) constituting the multilayer ceramic substrates, insufficient mechanical strength may be achieved for the substrates in some cases.

Therefore, there is actually a need for more highly reliable multilayer ceramic substrates.

The present invention is intended to solve the problems mentioned above, and an object of the present invention is to provide a highly reliable multilayer ceramic substrate which is excellent in substrate mechanical strength such as transverse strength, also high in bonding strength of surface electrodes to surface-layer sections of the multilayer ceramic substrate, moreover, high in insulation resistance for the surface-layer sections (ceramic layers) constituting the multilayer ceramic substrate, and able to sufficiently ensure insulation (interlayer insulation) between the surface electrodes and internal electrodes opposed to the surface electrodes with the surface-layer sections interposed therebetween, and an electronic component using the substrate.

In order to solve the problems mentioned above, a multilayer ceramic substrate includes:

an inner-layer section, surface-layer sections stacked on both front and back principal surfaces of the inner-layer section, and a surface electrode provided on at least one surface of the surface-layer sections, wherein

the surface-layer sections are formed by firing a glass ceramic based material containing SiO₂-MO (provided that MO is at least one selected from the group consisting of CaO, MgO, SrO, and BaO)—B₂O₃—Al₂O₃ based glass and an Al₂O₃ filler;

the coefficient of thermal expansion in the surface-layer sections is lower than the coefficient of thermal expansion in the inner-layer section, and

the peak intensity ratio through an XRD analysis between MAl₂Si₂O₈ (M is at least one selected from the group consisting of Ca, Mg, Sr, and Ba) as a crystal deposited onto the surface-layer sections and Al₂O₃ in the surface-layer sections falls within the range of the following formula (1):

0.05≦(MAl₂Si₂O₈/Al₂O₃)≦5 (1).

It is to be noted that in the present invention, for example, glass containing SiO₂ and MO (provided that MO is at least one selected from CaO, MgO, SrO, and BaO), where the proportion between SiO₂ and MO falls within the range of SiO₂:MO=23:7 to 17:13 (molar ratio) can be used as the glass for use in the surface-layer sections, that is, the glass containing SiO₂, MO (an oxide of at least one selected from the group consisting of Ca, Mg, Sr, and Ba), and Al₂O₃.

However, the glass for use in the surface-layer sections is preferably glass which is likely to deposit a crystal of MAl₂Si₂O₈, and it is thus desirable to use glass in which the ratio between SiO₂ and MO is adjusted so as to be close to the composition of the deposited crystal. More specifically, it is desirable to use, as the glass for use in the surface-layer sections, glass in which the ratio between SiO₂ and MO (for example, CaO) is brought close to 2 (SiO₂/MO=2) in terms of molar ratio.

In addition, in the multilayer ceramic substrate according to the present invention, the inner-layer section is also desirably formed by firing a glass ceramic based material containing the SiO₂-MO (provided that MO is at least one selected from the group consisting of CaO, MgO, SrO, and BaO)—B₂O₃—Al₂O₃ based glass and the Al₂O₃ filler. It is to be noted that the examples of glass for use in the inner-layer section include glass in which the proportion between SiO₂ and MO falls within the range of SiO₂:MO=19:11 to 11:19 in terms of molar ratio. The glass for use in the inner-layer section is advantageous in terms of mechanical strength characteristics when an appropriate amount of crystal is deposited from the glass in a firing step in the manufacture of the substrate, and is thus desirably likely to deposit MSiO₃, and accordingly, it is desirable to use glass in which the ratio between SiO₂ and MO is brought close to 1 (SiO₂/MO=1) in terms of molar ratio so as to be close to the composition of the deposited crystal.

In addition, the SiO₂ contained in the glass constituting the surface-layer sections preferably falls within the range of 34 to 73 weight % typically, whereas the SiO₂ contained in the glass contained in the material constituting the inner-layer section preferably falls within the range of 22 to 60 weight % typically.

More specifically, the glass contained in the material constituting the surface-layer sections preferably contains 34 to 73 weight % of SiO₂, such an amount of MO that leads to SiO₂/MO (molar ratio) around 2, up to 30 weight % of B₂O₃, and up to 30 weight % of Al₂O₃, whereas the glass contained in the material constituting the inner-layer section preferably contains 22 to 60 weight % of SiO₂, such an amount of MO that leads to SiO₂/MO (molar ratio) around 1, up to 20 weight % of B₂O₃, and up to 30 weight % of Al₂O₃.

Further, in the present invention, the material constituting the surface-layer sections desirably contains Al₂O as a filler in the range of 30 to 60 weight %.

In addition, the material constituting the inner-layer section preferably contains Al₂O₃ as a filler in the range of 40 to 70 weight %.

In addition, in the multilayer ceramic substrate according to the present invention, the crystallization temperature of the glass contained in the surface-layer sections preferably falls within the range of 910° C. to 950° C.

Further, methods for adjusting the crystallization temperature of the glass include:

(a) a method of adding a seed crystal for promoting crystallization in advance to the glass;

(b) a method of varying the particle sizes of the glass and Al₂O₃ filler in the case of the SiO₂-MO (provided that MO is at least one selected from the group consisting of CaO, MgO, SrO, and BaO)—B₂O₃—Al₂O₃ based glass; and

(c) a method of combining the (a) and (b) mentioned above, and in the present invention, it is possible to apply any of the methods.

Specifically, when the additive amount of the seed crystal is increased in the case of using the SiO₂-MO—B₂O₃—Al₂O₃ based glass, the crystallization temperature of the glass is lowered to make MAl₂Si₂O₈ likely to be deposited.

In addition, when the glass and the Al₂O₃ filler are reduced in particle size, MAl₂Si₂O₈ is made likely to be deposited because the reaction between the both is accelerated.

Furthermore, an electronic component according the present invention is characterized in that a surface-mounted chip component is mounted on the surface electrode of the multilayer ceramic substrate according to the present invention.

The multi-layer ceramic substrate according to the present invention has the stacked structure obtained by stacking the inner-layer section and the surface-layer sections located on both principal surfaces of the inner-layer section, where the surface-layer sections are formed by firing the glass ceramic based material containing the glass and the Al₂O₃ filler as described above, the coefficient of thermal expansion in the surface-layer sections is lower than the coefficient of thermal expansion in the inner-layer section, and the peak intensity ratio through an XRD analysis between MAl₂Si₂O₈ as a crystal deposited on the surface-layer sections and Al₂O₃ in the surface-layer sections falls within the range of 0.05≦(MAl₂Si₂O₈/Al₂O₃)≦5. Thus, it becomes possible to achieve a highly reliable multilayer ceramic substrate which is excellent in mechanical strength such as transverse strength, high in bonding strength of the surface electrodes to the surface-layer sections, high in withstand voltage for the surface-layer sections (ceramic layers), and able to sufficiently ensure insulation (interlayer insulation) between the surface electrodes and internal electrodes opposed to the surface electrodes with the surface layers interposed therebetween.

This advantageous effect is believed to be achieved by the following mechanism.

The excessively crystallized glass in the surface-layer sections constituting the multilayer ceramic substrate will result in a decrease in the amount of uncrystallized glass existing in the surface-layer sections, thus failing to ensure sufficient adhesion to the surface electrodes, and decreasing the bonding strength of the surface electrode to the surface layers of the multilayer ceramic substrate.

On the other hand, the excessively low crystallinity of the glass in the surface-layer sections will decrease the transverse strength of the multilayer ceramic substrate. This is because the crystallinity of the glass affects the ease of allowing stress to escape when compressive stress is applied to the surface-layer sections. More specifically, the low crystallinity of the glass in the surface-layer sections makes compressive stress generated in the surface-layer sections likely to be relaxed because of a lot of uncrystallized soft glass left, whereas the progressive crystallization of the glass in the surface-layer sections makes compressive stress less likely to be relaxed due to the existence of hard crystals, thereby making it easier to achieve the effect of the improvement in the strength of the entire multilayer ceramic substrate by the difference in coefficient of thermal expansion between the surface-layer sections and the inner-layer section.

Moreover, the excessively low crystallinity of the glass in the surface-layer sections will result in an increased proportion of uncrystallized glass existing in the surface-layer sections, thereby making the metal constituting the surface electrodes likely to diffuse into the glass, and decreasing the withstand voltage of the surface-layer sections to cause defective insulation.

More specifically, the peak intensity ratio between MAl₂Si₂O₈ and Al₂O₃ through an XRD analysis serves as an index for figuring out the crystallinity of the glass in the surface-layer sections, and the peak intensity ratio kept in the range of 0.05≦(MAl₂Si₂O₈/Al₂O₃)≦5 thus makes it possible to achieve desirable crystallinity to achieve the function effect of the present invention as described above.

In addition, in the present invention, the surface-layer sections meet, in the case of containing the SiO₂-MO (provided that MO is at least one selected from the group consisting of CaO, MgO, SrO, and BaO)—B₂O₃—Al₂O₃ based glass and the Al₂O₃ filler, the above-mentioned requirements of the present invention, that is, the requirements for the peak intensity ratio between MAl₂Si₂O₈ (M is at least one selected from the group consisting of Ca, Mg, Sr, and Ba) and Al₂O₃ to fall within the range of 0.05≦(MAl₂SiO₂O₈/Al₂O₃)≦5, thereby making it possible to further ensure that a multilayer ceramic substrate is achieved which produces the function effect of the present invention as described above.

Furthermore, the crystallization temperature of the glass contained in the surface-layer sections preferably falls within the range of 910° C. to 950° C., because it becomes possible to achieve, with more certainty, the function effect of the present invention as described above.

Furthermore, the electronic component according to the present invention has the surface-mounted chip component mounted on the surface electrode which is excellent in bonding strength to the surface-layer sections of the multilayer ceramic substrate, and thus can provide an electronic component which is excellent in mounting reliability.

### BRIEF EXPLANATION OF THE DRAWINGS

FIG. 1 is a front cross-sectional view illustrating the configuration of an electronic component according to an embodiment of the present invention, with chip components mounted on a surface of a multilayer ceramic substrate according to an embodiment of the present invention.

FIG. 2 is a front cross-sectional view illustrating the configuration of a composite stacked body which has green sheets for surface-layer section formation stacked on both principal surfaces of green sheets for inner-layer section formation, and further has green sheets for constrained layers stacked outermost.

FIG. 3 is a front cross-sectional view illustrating the configuration of a multilayer ceramic substrate (a multilayer ceramic substrate before mounting chip components such as semiconductor devices and chip capacitors) obtained by removing constrained layers after firing.

### DETAILED DESCRIPTION OF THE INVENTION

Features of the present invention will be described in more detail with reference to embodiments of the present invention below.

[Configuration of Multilayer Ceramic Substrate]

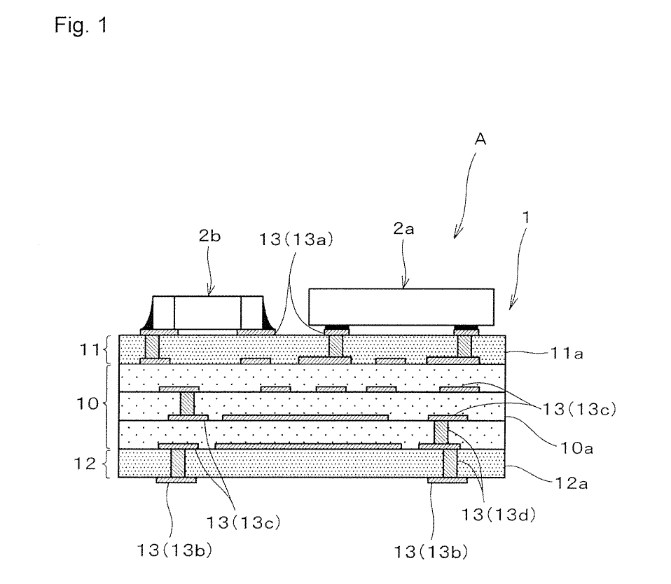

FIG. 1 is a front cross-sectional view illustrating an electronic component according to an embodiment of the present invention, where chip components are mounted on surface electrodes of a multilayer ceramic substrate according to an embodiment of the present invention.

The multilayer ceramic substrate 1 constituting the electronic component A has a stacked structure including an inner-layer section 10 and first and second surface-layer sections 11, 12 stacked and provided on both principal surfaces of the inner-layer section 10 so as to sandwich the inner-layer section 10 in a stacking direction.

It is to be noted that the inner-layer section 10 includes at least one inner-layer section ceramic layer 10a, whereas the first and second surface-layer sections 11, 12 also respectively include at least surface-layer section ceramic layers 11a, 12a.

In addition, this multilayer ceramic substrate 1 includes conductors 13 provided on surfaces of the substrate and within the substrate.

The conductors 13 include: surface electrodes 13a formed on one principal surface (upper surface) of the multilayer ceramic substrate 1, on which chip components are mounted such as, for example, a semiconductor device 2a and a chip capacitor 2b; surface electrodes 13b provided on the other principal surface, which function as electrical connection means in the case of mounting the multilayer ceramic substrate 1 onto a mother board, not shown; inner conductors 13c provided within the multilayer ceramic substrate 1, which constitute passive elements such as capacitors and inductors, or function as connecting wirings for electrical connections between elements; and via hole conductors 13d for interlayer connections.

Further, in the case of the multilayer ceramic substrate 1 according to the present invention, as the materials constituting the inner-layer section 10 and the first and second surface-layer sections 11, 12, glass ceramics capable of being fired at low temperature are used which contains SiO₂-MO (provided that MO is at least one selected from the group consisting of CaO, MgO, SrO, and BaO, which is CaO in this embodiment) —B₂O₃—Al₂O₃ based glass and a Al₂O₃ filler.

In addition, the first and second surface-layer sections 11, 12 are adapted so that the coefficient of thermal expansion therein is lower than the coefficient of thermal expansion in the inner-layer section 10, and the peak intensity ratio (CaAl₂Si₂O₈/Al₉O₃) between CaAl₂Si₂O₈ (anorthite) and Al₂O₃ through an XRD analysis falls within the range of 0.05 to 5 in the first and second surface-layer sections 11, 12.

While a case of Ca for M and CaO for MO has been explained by way of example in this embodiment as described above, M may be at least one selected from the group consisting of Ca, Mg, Sr, and Ba, and Mo may be oxides thereof.

It is to be noted that the glass composition is preferably close to the deposited crystal composition, because the multilayer ceramic substrate according to the present invention is more advantageous in mechanical strength properties when an appropriate amount of crystal is deposited from the glass in a firing step in the manufacture of the substrate.

For example, in the case of SiO₂-MO—Al₂O₃—B₂O₃ based glass, crystals of MAl₂Si₂O₈ and MSiO₃ are likely to be deposited, and it is thus desirable to adjust the ratio between SiO₂ and MO so as to be close to the deposited crystal composition.

Specifically, in regard to the glass composition in the surface-layer sections 11, 12, the ratio between SiO₂ and MO (for example, CaO) is desirably brought close to 2 (SiO₂/MO=2) in terms of molar ratio, from the viewpoint of depositing more crystals of MAl₂Si₂O₈ in order to reduce the coefficient of thermal expansion.

In addition, in regard to the glass composition in the inner-layer section 10, it is preferable to deposit more crystals of MSiO₃, and from that viewpoint, the ratio between SiO₂ and MO is desirably brought close to 1 (SiO₂/MO=1) in terms of molar ratio.

It is to be noted that the glass composition in the inner-layer section 10, which has a higher MO ratio as compared with the surface-layer sections 11, 12, is subjected to erosion in plating treatment after firing, but not exposed at the surface section, and thus less likely to be fatally damaged.

The SiC₂ in the glass, which is excessively increased in the surface-layer sections 11, 12 in order to further increase the difference in coefficient of thermal expansion, causes defective sintering because of the glass viscosity insufficiently reduced during firing, whereas the excessively increased MO therein has a tendency to fail to produce a sufficient difference in coefficient of thermal expansion.

In addition, the MO in the glass, which is excessively increased in the inner-layer 10 in order to further increase the difference in coefficient of thermal expansion, unfavorably decreases the moisture resistance to cause defective insulation. In addition, the excessively increased SiO₂ therein has a tendency to fail to produce a sufficient difference in coefficient of thermal expansion.

From the foregoing, the ratio between SiO₂ and MO in the glass preferably falls within the ranges as mentioned previously in the surface-layer sections 11, 12 and the inner layer section 10, respectively

In addition, the glass contained in the material constituting the surface-layer sections 11, 12 desirably contains: 34 to 73 weight % of SiO₂; such an amount of MO that leads to SiO₂/MO (molar ratio) around 2; up to 30 weight % of B₂O₂; and up to 30 weight % of Al₂O₃.

In addition, the glass contained in the material constituting the inner-layer section 10 desirably contains: 22 to 60 weight % of SiO₂; such an amount of MO that leads to SiO₂/MO (molar ratio) around 1; up to 20 weight % of B₂O₃; and up to 30 weight % of Al₂O₃.

Here are the reasons.

(a) While B₂O₃ functions to provide the glass with an appropriate viscosity so as to smoothly progress sintering during firing, the excessively increased B₂O₃ excessively decreases the viscosity, thus leading to over-firing, and pores produced at the surface are likely to cause defective insulation. On the other hand, the excessively decreased B₂O₃ increases the viscosity to make defective sintering likely to be caused.

(b) While Al₂O₃ serves as a constituent of deposited crystals in the case of the surface-layer sections 11, 12, the excessively increased or decreased Al₂O₃ makes crystals less likely to be deposited.

(c) In addition, the Al₂O₃ improves the chemical stability of the glass, and thus, in the case of the inner-layer section 10 with relatively more MO, the increased proportion of Al₂O₃ improves the plating resistance and moisture resistance. On the other hand, with respect to the coefficient of thermal expansion, Al₂O₃ makes an intermediate contribution between SiO₂ and MO, and thus, the excessively increased amount of Al₂O₃ makes it difficult to ensure the difference in coefficient of thermal expansion between the surface-layer sections and the inner-layer section.

Furthermore, more preferably, the material constituting the surface-layer sections 11, 12 contains 30 to 60 weight % of Al₂O₃ as a filler, whereas the material constituting the inner-layer section 10 contains 40 to 70 weight % of Al₂O₃ as a filler.

Here are the reasons.

The Al₂O₃ filler contributes to an improvement in mechanical strength. Therefore, the excessively decreased Al₂O₃ filler leads to failure to achieve sufficient strength. In particular, even when the inner-layer section 10 to which tensile stress is applied has insufficient mechanical strength, the inner-layer section 10 will be destroyed therefrom, thus resulting in failure to sufficiently achieve the effect of the surface-layer sections 11, 12 reinforced with compressive stress. Accordingly, the Al₂O₃ filler contained in the inner-layer section 10 more than in the surface-layer sections 11, 12 to improve the strength, thereby withstanding even a larger difference in coefficient of thermal expansion, and the effect of the reinforced surface-layer sections 11, 12 can be achieved with more certainty.

In addition, the Al₂O₃ filler also, with respect to the coefficient of thermal expansion, makes an intermediate contribution between the glass in the surface-layer sections 11, 12 and the glass in the inner-layer section 10, and thus, the excessively increased Al₂O₃ filler makes it impossible to ensure the difference in coefficient of thermal expansion.

[Preparation of Multilayer Ceramic Substrate]

Next, a method for manufacturing the multilayer ceramic substrate 1 described above will be described.

<Preparation of Green Sheets for Surface-Layer Section Formation>

Slurry prepared by blending a mixed powder of SiO₂—CaO—B₂O₃—Al₂O₃ based glass A and an Al₂O₃ powder as a filler with a solvent, a dispersant, a binder, and a plasticizer was applied onto a PET film to prepare green sheets for surface-layer section formation.

It is to be noted that SiO₂—CaO—B₂O₃—Al₂O₃ based glass of composition as shown in Table 1 was used as the glass A. Further, the class A has a composition adjusted to provide SiO₂/MO (molar ratio) around 2.

TABLE 1

| Constituent | Parts by Weight |
|---|---|
| SiO₂ | 55 |
| CaO | 25 |
| B₂O₃ | 10 |
| Al₂O₃ | 10 |

It is to be noted that the blending ratio between the glass A and the Al₂O₃ filler was adjusted for 6:4 in terms of ratio by weight.

In this embodiment, green sheets with the crystallization temperature of the glass contained therein in the range of 900° C.≦crystallization temperature≦970° C. were prepared as the green sheets for surface-layer section formation.

For varying the crystallization temperature of the glass in the range of 900° C.≦crystallization temperature 970° C., the crystallization temperature of the glass was varied in the range mentioned above by adjusting the additive amount of a seed crystal for promoting crystallization.

Specifically, the crystallization temperature was varied in the range of 900 to 970° C. by adding the seed crystal in the proportion as shown in Table 3 (the proportion to the total amount of the glass and Al₂O₃ filler).

However, the method for varying the crystallization temperature of the glass is not limited to the method of adding the seed crystal, but it is also possible to apply a method of varying the particle sizes of the glass or Al₂O₃ filler, or a method of combining both the method of adding the seed crystal and the method of varying the particle sizes.

<Preparation of Green Sheets for Inner-Layer Section Formation>

Slurry prepared by blending a mixed powder of SiO₂—CaO—B₂O₃—Al₂O based glass B and an Al₂O₃ powder as a filler with a solvent, a dispersant, a binder, and a plasticizer was applied onto a PET film to prepare green sheets for inner-layer section formation.

It is to be noted that SiO₂—CaO—B₂O₃—Al₂O₃ based glass of composition as shown in Table 2 was used as the glass B. Further, the glass B has a composition adjusted to provide SiO₂/MO (molar ratio) around 1.

TABLE 2

| Constituent | Parts by Weight |
|---|---|
| SiO₂ | 40 |
| CaO | 40 |
| B₂O₃ | 10 |
| Al₂O₃ | 10 |

It is to be noted that the blending ratio between the glass B and the Al₂O₃ filler was adjusted for 5:5 in terms of ratio by weight.

<Preparation of Green Sheets for Constrained Layers>

Slurry obtained by blending an Al₂O₃ powder with a solvent, a dispersant, a binder, and a plasticizer was applied onto a PET film to prepare green sheets for constrained layers.

<Preparation of Electroconductive Paste for Formation of Surface Electrode and Inner Conductor>

An Ag powder as an electroconductive component was blended with an organic vehicle and a solvent, and kneaded to prepare an electroconductive paste (Ag paste) for the formation of surface electrodes and inner conductors.

<Printing of Electroconductive Paste onto Green Sheets>

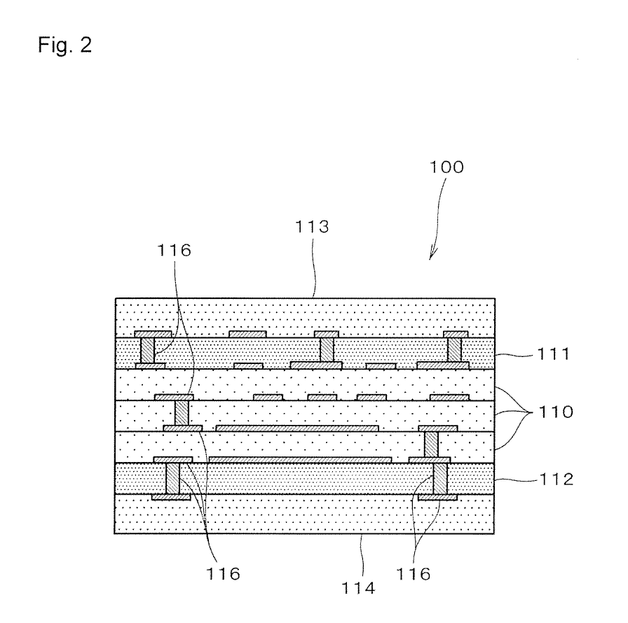

Then, the Ag paste 116 (see FIG. 2) for the formation of surface electrodes and inner conductors was printed onto the green sheets for surface-layer section formation and green sheets for inner-layer section formation prepared in the way described above.

<Stacking and Firing>

Then, the respective green sheets with the Ag paste 116 printed thereon and the green sheets for constrained layers were stacked, and subjected to pressure bonding to form a composite stacked body 100 structured to have green sheets 111,112 for surface-layer section formation stacked on both principal surfaces of green sheets 110 for inner-layer section formation, and further have green sheets 113, 114 for constrained layers stacked outermost as schematically illustrated in FIG. 2.

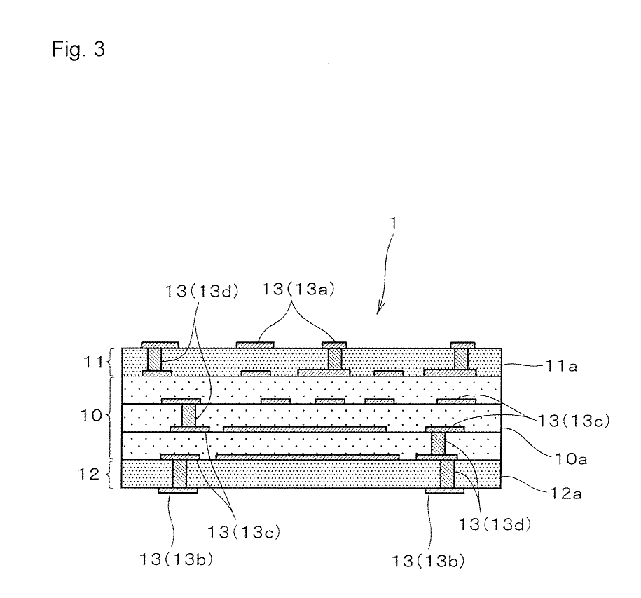

Then, this composite stacked body 100 is subjected firing at a temperature at which the green sheets 113, 114 for constrained layers are not sintered, whereas the other substrate materials (the green sheets 110 for inner-layer part formation, the green sheets 111, 112 for surface-layer section formation) and the Ag paste 116 are sufficiently sintered. After the firing, the Ag paste 116 serves as the conductors 13 such as the surface electrodes 13a, 13B, the inner conductors 13c, and the via hole conductors 13d (see FIGS. 1 and 3).

The multilayer ceramic substrate (multilayer ceramic substrate before mounting chip components such as the semiconductor device 2a (FIG. 1) and the chip capacitor 2b (FIG. 1)) 1 as shown in FIG. 3 was obtained by removing the constrained layers from the composite stacked body after the firing.

The shrinkage of the green sheets for surface-layer section formation and the green sheets for inner-layer section formation in the principal surface direction in the firing step can be suppressed because the composite stacked body with the green sheets for constrained layers placed as the outermost layers is subjected to firing in the firing step in this embodiment as described above. Therefore, undesirable deformations of the multilayer ceramic substrate can be suppressed to increase the dimensional accuracy, and interlayer peeling between the surface-layer sections and the inner-layer section can be made less likely to be caused during the firing.

Further, in this embodiment, as shown in Table 3, multilayer ceramic substrates (samples according to Examples 1 to 5 in Table 3) which meet the requirements of the present invention with the peak intensity ratio between CaAl₂Si₂O₈ and Al₂O₃ through an XRD analysis within the range of 0.05 to 5 were prepared as well as samples (samples according to Comparative Examples 1 to 3) with the peak intensity ratio between CaAl₂Si₂O₈ and Al₂O₃ outside the range of 0.05 to 5, and characteristics were evaluated for each sample to confirm advantageous effects of the present invention.

[Evaluation of Characteristics]

For each of the prepared multilayer ceramic substrates,

(1) the crystallization temperature for the surface-layer sections,

(2) the peak intensity ratio of CaAl₂Si₂O₈/Al₂O₃ in the surface-layer sections (the peak intensity ratio through an XRD analysis),

(3) the coefficient of thermal expansion in the surface-layer sections,

(4) the coefficient of thermal expansion in the inner-layer section,

(5) the electrode bonding strength,

(6) the transverse strength, and

(7) the insulation resistance percent defective in the surface-layer sections were examined. The results are shown in Table 3.

TABLE 3

| | | | | | | | | Insulation |
|---|---|---|---|---|---|---|---|---|
| | | | Peak Intensity | Coefficient | Coefficient | | | Resistance |
| | Crystallization | Additive | Ratio of | of Thermal | of Thermal | | | Percent |
| | Temperature for | Amount of | CaAl₂Si₂O₈/Al₂O₃ | Expansion in | Expansion in | Electrode | Transverse | Defective in |
| | Surface-Layer | Seed Crystal | in Surface- | Surface-Layer | Inner-Layer | Bonding | Strength | Surface-Layer |
| | Section (° C.) | (weight %) | Layer Sections | Section | Section | Strength (N) | (Mpa) | Section (%) |
| Comparative | 970 | 0.001 | 0.01 | 7.4 | 7.5 | 38 | 370 | 15 |
| Example 1 | | | | | | | | |
| Comparative | 960 | 0.005 | 0.03 | 7.3 | 7.5 | 35 | 375 | 5 |
| Example 2 | | | | | | | | |
| Comparative | 900 | 5.0 | 7 | 6.5 | 7.5 | 13 | 535 | 0 |
| Example 3 | | | | | | | | |
| Example 1 | 950 | 0.01 | 0.05 | 7.1 | 7.5 | 39 | 502 | 0 |
| Example 2 | 940 | 0.05 | 0.1 | 7 | 7.5 | 38 | 506 | 0 |
| Example 3 | 930 | 0.1 | 1 | 6.8 | 7.5 | 35 | 512 | 0 |
| Example 4 | 920 | 0.5 | 3 | 6.7 | 7.5 | 37 | 520 | 0 |
| Example 5 | 910 | 1.0 | 5 | 6.6 | 7.5 | 33 | 530 | 0 |

It is to be noted that the crystallization temperature for the surface-layer section in Table 3 refers to the peak temperature of an exothermic reaction associated with crystal deposition from the glass when the ceramic green sheets are subjected to firing, which is a value measured by differential scanning calorimetry (DSC).

In addition, the peak intensity ratio of CaAl₂Si₂O₈/Al₂O₃ in the surface-layer sections is obtained by figuring out the ratio (CaAl₂Si₂O₈/Al₂O₃) between peaks checked at angles around 28° for CaAl₂Si₂O₈ (anorthite) and around 25.6° for Al₂O₃ through an XRD analysis with the use of CuKα as an X-ray source.

In addition, the coefficients of thermal expansion in the surface-layer sections and inner-layer section are obtained with the use of a thermo-mechanical analyzer (TMA).

The electrode bonding strength is obtained by conducting a tension test on an electrode of 2 mm under the condition of tension rate: 20 mm/min.

In addition, the transverse strength is measured by conducting a three-point bending test on the multilayer ceramic substrates.

Furthermore, the insulation resistance percent defective in the surface-layer sections is obtained by checking the insulation resistance in the case of applying 50 V with an insulation resistance measuring machine, which is a percent defective figured out by regarding samples of less than 10¹⁰Ω in resistance as defectives. The number of pieces evaluated was 100.

As shown in Table 3, in the case of the samples according to Comparative Examples 1 and 2 with the reduced additive amount of the seed crystal for increasing the crystallization temperature for the surface-layer sections, that is, the sample according to Comparative Example 1 with 0.01 as the peak intensity ratio of CaAl₂Si₂O₈/Al₂O₃ in the surface-layer sections and the sample according to Comparative Example 2 with 0.03 as the peak intensity ratio of CaAl₂Si₂O₈/Al₂O₃ in the surface-layer sections, it has been confirmed that the electrode bonding strength is increased, while the transverse strength is decreased. This is due to the fact that a small amount of CaAl₂Si₂O₈ deposited in the fired surface-layer sections results in an increase in the amount of residual glass.

However, in the case of the samples according to Comparative Examples 1 and 2, it has been confirmed that the decreased crystallinity thus unfavorably increases the amount of Ag diffusion into the glass to decrease the resistance of the surface-layer sections, thereby increasing the insulation resistance percent defective.

in addition, in the case of the sample according to Comparative Example 3 with the increased additive amount of the seed crystal for lowering the crystallization temperature for the surface-layer sections, that is, the sample with 7 as the peak intensity ratio of CaAl₂Si₂O₈/Al₂O₃ in the surface-layer sections, it has been confirmed that the transverse strength is increased because of the high degree of CaAl₂Si₂O₈ deposition in the surface-layer sections. In addition, it has been confirmed that the reduced amount of residual glass thus decreases the amount of Ag diffusion into the glass to increase the resistance of the surface-layer sections, thereby preventing defective insulation from being caused.

However, in the case of the sample according to Comparative Example 3, it has been confirmed that the excessively increased degree of CaAl₂Si₂O₈ deposition in the surface-layer sections reduces the amount of residual glass, thus resulting in insufficient electrode bonding strength.

On the other hand, in the case of the samples according to Examples 1 to 5 in Table 3, for which the crystallization temperature for the surface-layer sections was set in an appropriate range to allow the beak intensity ratio of CaAl₂Si₂O₈/Al₂O₃ in the surface-layer sections to meet the requirements of the present invention (the requirements of (0.05≦CaAl₂Si₂O₈/Al₂O₃), it has been confirmed that it becomes possible to improve the transverse strength and the electrode bonding strength, and defective insulation resistance can be prevented in the surface-layer sections.

It is to be noted that while a case of CaO for MO has been explained by way of example in the embodiment described above, it has been confirmed that similar effects are achieved even when MO is any of MgO, SrO, and BaO.

The present invention is further not to be considered limited to the embodiment described above even in other respects, but various applications and modifications can be made within the scope of the invention, regarding the constituent material of the surface electrodes, how to provide the surface electrodes and the inner conductors specifically, the thicknesses of the surface-layer sections and inner-layer section, how to provide the sections, etc.

### DESCRIPTION OF REFERENCE SYMBOLS

A—electronic component
1—multilayer ceramic substrate
2a—semiconductor device
2b—chip capacitor
10—inner-layer section
10a—inner-layer section ceramic layer
11—first surface-layer section
12—second surface-layer section
11a,12a—surface-layer section ceramic layers
13—conductor
13a,13b—surface electrodes
13c—inner conductor
13d—via hole conductor
100—composite stacked body
110—green sheet for inner-layer section formation
111,112—green sheets for surface-layer section formation
113,114—green sheets for constrained layer
116—Ag paste

1. A multilayer ceramic substrate comprising:
an inner-layer section;
surface-layer sections on opposed first and second surfaces of the inner-layer section; and
a surface electrode on at least one surface of the surface-layer sections, wherein
the surface-layer sections are a fired glass ceramic based material containing SiO₂-MO—B₂O₃—Al₂O₃ based glass and an Al₂O₃ filler, and MO is at least one selected from the group consisting of CaO, MgO, SrO, and BaO,
a first coefficient of thermal expansion in the surface-layer sections is lower than a second coefficient of thermal expansion in the inner-layer section,
a peak intensity ratio through an XRD analysis between MAl₂Si₃O₈ as a crystal deposited on the surface-layer sections and Al₂O₃ in the surface-layer sections falls within 0.05≦(MAl₂Si₂O₈/Al₂O₃)≦5, and
M is at least one selected from the group consisting of Ca, Mg, Sr, Ba and oxides thereof.

2. The multilayer ceramic substrate according to claim 1, wherein a crystallization temperature of the glass contained in the surface-layer sections falls within a range of 910° C. to 950° C.

3. The multilayer ceramic substrate according to claim 1, wherein a glass contained in the material of the surface-layer sections contains 34 to 73 weight % of SiO₂; an amount of MO wherein a molar ration of SiO₂/MO is approximately 2; up to 30 weight % of B₂O₃; and up to 30 weight % of Al₂O₃.

4. The multilayer ceramic substrate according to claim 3, wherein a glass contained in the material of the inner-layer section contains 22 to 60 weight % of SiO₂; an amount of MO wherein a molar ration of SiO₂/MO is approximately 1; up to 20 weight % of B₂O₃; and up to 30 weight of Al₂O₃.

5. The multilayer ceramic substrate according to claim 1, wherein a glass contained in the material of the inner-layer section contains 22 to 60 weight % of SiO₂; an amount of MO wherein a molar ration of SiO₂/MO is approximately 1; up to 20 weight % of B₂O₃; and up to 30 weight % of Al₂O₃.

6. The multilayer ceramic substrate according to claim 1, wherein the material of the surface-layer sections contains 30 to 60 weight % of Al₂O₃ as a filler, and the material of the inner-layer section contains 40 to 70 weight % of Al₂O₃ as a filler.

7. An electronic component comprising:
the multilayer ceramic substrate according to claim 1; and
a surface-mounted chip component mounted on the surface electrode.
